(19) United States
(12) Patent Application Publication
(10) Pub. No.: US 2026/0239674 A1
(43) Pub. Date: Aug. 13, 2026

(54) SEMICONDUCTOR DEVICE, ELECTRONIC APPARATUS INCLUDING THE SAME, AND METHOD OF MANUFACTURING THE SEMICONDUCTOR DEVICE

(71) Applicant: Samsung Electronics Co., Ltd., Suwon-si (KR)

(72) Inventors: Hajun SUNG, Suwon-si (KR); Youngjae KANG, Suwon-si (KR); Bonwon KOO, Suwon-si (KR); Sangwook KIM, Suwon-si (KR); Kiyeon YANG, Suwon-si (KR); Jeeeun YANG, Suwon-si (KR); Minwoo CHOI, Suwon-si (KR); Jinseong HEO, Suwon-si (KR)

(73) Assignee: Samsung Electronics Co., Ltd., Suwon-si (KR)

(21) Appl. No.: 19/374,709

(22) Filed: Oct. 30, 2025

(30) Foreign Application Priority Data
Feb. 11, 2025 (KR) 10-2025-0017513

(51) Int. Cl. H10D 30/67; G11C 13/00; H10B 51/10; H10B 51/20; H10B 51/30; H10D 30/00; H10D 30/01

(52) U.S. Cl. CPC H10D 30/6755; H10B 51/10; H10B 51/20; H10B 51/30; H10D 30/0314; H10D 30/0318; H10D 30/6728; H10D 30/6731; H10D 30/6733; H10D 30/6735; H10D 30/6736; H10D 30/6757; G11C 13/0007; H10D 30/502

(57) ABSTRACT

Provided are a semiconductor device, an electronic apparatus including the same, and a method of manufacturing the semiconductor device. The semiconductor device may include a channel, a source electrode electrically connected to the channel, a drain electrode electrically connected to the channel and spaced apart from the source electrode, a gate insulating layer on the channel, and a gate electrode on the gate insulating layer. The channel may include InₐTe_{b}O_{c} (wherein, a+b=100, a<50, b>50, and c is less than the chemical stoichiometric value).

### CROSS-REFERENCE TO RELATED APPLICATION

This application is based on and claims priority under 35 U.S.C. § 119 to Korean Patent Application No. 10-2025-0017513, filed on Feb. 11, 2025 in the Korean Intellectual Property Office, the disclosure of which is incorporated by reference herein in its entirety.

### BACKGROUND

### 1. Field

One or more embodiments relate to a semiconductor device including a p-type channel, an electronic apparatus including the same, and a method of manufacturing the semiconductor device.

### 2. Description of the Related Art

Oxide semiconductors with high electrical performance, which may be used in semiconductor devices, are mostly n-type semiconductors in which electrons more efficiently transported at room temperature. The development of p-type semiconductors in which hole transport is available is limited in applications across various fields. Indium gallium zinc oxide (InGaZnO) is commonly used as an example of an n-type semiconductor and may be applied to backplane transistors for driving organic light-emitting diode (OLED) displays.

Materials such as tin oxide (SnO) have been studied as p-type semiconductors, but SnO exhibits lower hole field-effect mobility and a lower ON/OFF current ratio than n-type semiconductor oxides. Thus, there is a demand for p-type oxide semiconductors with excellent electrical properties to be used in various semiconductor devices for numerous applications.

### SUMMARY

One or more embodiments provide a semiconductor device including a p-type channel.

One or more embodiments provide an electronic apparatus that includes the semiconductor device including the p-type channel.

One or more embodiments provide a method of manufacturing the semiconductor device including a p-type channel.

Additional aspects will be set forth in part in the description which follows and, in part, will be apparent from the description, or may be learned by practice of the presented embodiments of the disclosure.

According to an example embodiment, a semiconductor device may include a channel, a source electrode electrically connected to the channel, a drain electrode electrically connected to the channel and spaced apart from the source electrode, a gate insulating layer on the channel, and a gate electrode on the gate insulating layer, wherein the channel includes InₐTe_{b}O_{c} (where, a+b=100, a<50, b>50, and c is less than a chemical stoichiometric value).

In some embodiments, in InₐTe_{b}O_{c}, a may be in a range of 12 to 40, and b may be in a range of 60 to 88.

In some embodiments, in InₐTe_{b}O_{c}, a ratio of b/a, may be greater than 1 and less than or equal to 7.

In some embodiments, an oxygen vacancy concentration in the channel may be in a range of 5% to 80%.

In some embodiments, the source electrode may be spaced apart from the drain electrode in a first direction, the first direction may be a same direction as a vertical direction of the semiconductor device, and a longitudinal direction of each of the channel, the gate insulating layer, and the gate electrode may be in the first direction.

In some embodiments, the channel may include a bottom portion contacting the source electrode, a first vertical extension extending from one end of the bottom portion in a direction perpendicular to the source electrode, and a second vertical extension extending from an other end of the bottom portion in the direction perpendicular to the source electrode.

In some embodiments, the gate insulating layer may include a ferroelectric substance.

In some embodiments, the channel, the gate insulating layer, and the gate electrode may be arranged concentrically. The gate electrode may include a first gate electrode and a second gate electrode that are spaced apart from each other. A spacer may be between the first gate electrode and the second gate electrode.

According to an example embodiment, a semiconductor device may include a channel including an n-type first channel and a p-type second channel on the n-type first channel, a source electrode and a drain electrode that are electrically connected to the channel, a gate electrode spaced apart from the channel, and a gate insulating layer between the channel and the gate electrode. The p-type second channel may include InₐTe_{b}O_{c} (where, a+b=100, a<50, b>50, and c is less than a chemical stoichiometric value).

In some embodiments, the n-type first channel may include an oxide including at least one of indium (In), zinc (Zn), tin (Sn), gallium (Ga), and hafnium (Hf).

According to another aspect of the disclosure, an electronic apparatus includes a host, a memory apparatus including at least one semiconductor device, and a memory controller configured to control the memory apparatus for at least one of a reading operation of data from the memory apparatus and a writing operation of data to a non-volatile memory apparatus, in response to a request from the host. Each semiconductor device among the at least one semiconductor device may include: a channel, a source electrode electrically connected to the channel, a drain electrode electrically connected to the channel and spaced apart from the source electrode, a gate insulating layer on the channel, and a gate electrode on the gate insulating layer. The channel may include InₐTe_{b}O_{c} (where, a+b=100, a<50, b>50, and c is less than a chemical stoichiometric value).

According to another aspect of the disclosure, a method of manufacturing a semiconductor device may include forming a channel on a substrate, the channel including In, Te, and O; adjusting a composition of the channel to InₐTe_{b}O_{c} (where, a<50, b>50, and c is less than a chemical stoichiometric value); forming a source electrode on one surface of the channel and forming a drain electrode on an opposite surface of the channel, forming a gate insulating layer on the channel; and forming a gate electrode on the gate insulating layer.

The method may further include forming a p-type channel between the source electrode and the channel, wherein the p-type channel may include oxide including at least one of In, Zn, Sn, Ga, and Hf.

### BRIEF DESCRIPTION OF THE DRAWINGS

The above and other aspects, features, and advantages of certain embodiments of the disclosure will be more apparent from the following description taken in conjunction with the accompanying drawings, in which:

FIG. 1 schematically illustrates a semiconductor device according to an embodiment;

FIG. 2A illustrates the density of states (DOS) with respect to the energy of indium oxide (In₂O₃), which is a Comparative Example;

FIG. 2B illustrates the DOS with respect to the energy of indium tellurium oxide having a composition of Te:In=3:1;

FIG. 2C illustrates the DOS with respect to the energy of indium tellurium oxide having a composition of Te:In=1:3;

FIG. 3A illustrates the DOS with respect to energy in a case where the composition has a Te:In ratio of 1:1 and oxygen is deficient by 20% relative to the chemical stoichiometric value;

FIG. 3B illustrates the DOS with respect to energy in a case where the composition has a Te:In ratio of 1:1 and oxygen is deficient by 10% relative to the chemical stoichiometric value;

FIG. 3C illustrates the DOS with respect to energy in a case where the composition has a Te:In ratio of 1:1 and oxygen has the chemical stoichiometric value;

FIG. 4A illustrates voltage-current characteristics of a semiconductor device including an In₁₂Te₈₈ channel, according to an embodiment;

FIG. 4B illustrates voltage-current characteristics of a semiconductor device including an In₂₅Te₇₅ channel, according to an embodiment;

FIG. 5 schematically illustrates an energy band diagram of In₂O₃ and indium tellurium oxide;

FIG. 6 schematically illustrates a semiconductor device according to another embodiment;

FIGS. 7 to 11 illustrate examples of semiconductor devices having vertical channel structures;

FIG. 12 is a horizontal cross-sectional view schematically illustrating a structure of a memory cell string of a memory device, according to an embodiment;

FIG. 13 is a vertical cross-sectional view of FIG. 12;

FIG. 14 illustrates a semiconductor device having a multichannel structure, according to an embodiment;

FIG. 15 is a flowchart of a method of manufacturing a semiconductor device, according to an embodiment;

FIG. 16 is a flowchart of a method of manufacturing a semiconductor device, according to another embodiment;

FIG. 17 illustrates an equivalent circuit of a memory device according to an embodiment;

FIG. 18 is a conceptual view schematically illustrating a device architecture applicable to an example electronic apparatus;

FIG. 19 is a block diagram of a memory system according to an embodiment; and

FIG. 20 is a block diagram of a neuromorphic apparatus and an external device connected thereto, according to an embodiment.

### DETAILED DESCRIPTION

Reference will now be made in detail to embodiments, examples of which are illustrated in the accompanying drawings, wherein like reference numerals refer to like elements throughout. In this regard, the present embodiments may have different forms and should not be construed as being limited to the descriptions set forth herein. Accordingly, the embodiments are merely described below, by referring to the figures, to explain aspects of the present description. As used herein, the term “and/or” includes any and all combinations of one or more of the associated listed items. Throughout the disclosure, the expression “at least one of a, b, or c” indicates only a, only b, only c, both a and b, both a and c, both b and c, all of a, b, and c, or variations thereof.

When the terms “about” or “substantially” are used in this specification in connection with a numerical value, it is intended that the associated numerical value includes a manufacturing or operational tolerance (e.g., ±10%) around the stated numerical value. Moreover, when the words “generally” and “substantially” are used in connection with geometric shapes, it is intended that precision of the geometric shape is not required but that latitude for the shape is within the scope of the disclosure. Further, regardless of whether numerical values or shapes are modified as “about” or “substantially,” it will be understood that these values and shapes should be construed as including a manufacturing or operational tolerance (e.g., ±10%) around the stated numerical values or shapes. When ranges are specified, the range includes all values therebetween such as increments of 0.1%.

While the term “equal to” is used in the description of example embodiments, it should be understood that some imprecisions may exist. Thus, when one element is referred to as “equal to” another element, it should be understood that an element or a value may be “equal to” another element within a desired manufacturing or operational tolerance range (e.g., ±10%).

The notion that elements are “substantially the same” may indicate that the element may be completely the same and may also indicate that the elements may be determined to be the same in consideration of errors or deviations occurring during a process.

Hereinafter, a semiconductor device, an electronic apparatus including the same, and a method of manufacturing the semiconductor device according to one or more embodiments are described in detail with reference to the attached drawings. Like reference numerals in the drawings denote like elements, and sizes of components in the drawings may be exaggerated for convenience of explanation. It will be understood that although the terms “first,” “second,” etc. may be used herein to describe various components, these components should not be limited by these terms. The terms are only used to distinguish one component from another.

Singular expressions include plural expressions unless the context clearly indicates otherwise. It will be further understood that the terms “comprises” and/or “comprising” used herein specify the presence of stated features or components, but do not preclude the presence or addition of one or more other features or components. Also, sizes or thicknesses of components in the drawings may be exaggerated for clarity. In addition, when a certain material layer is described as being present above a substrate or another layer, the material layer may be in direct contact with the substrate or the other layer, or there may be an intervening layer therebetween. Furthermore, materials forming each layer in the embodiments below are merely examples, and thus, alternative materials may also be used.

In addition, the terms “-er”, “-or”, and “module” described in the specification mean units for processing at least one function and operation and can be implemented by hardware components or software components and combinations thereof.

The particular implementations shown and described herein are illustrative examples of the disclosure and are not intended to otherwise limit the scope of the disclosure in any way. For the sake of brevity of the specification, existing electronics, control systems, software development, and other functional aspects of the systems may not be described in detail. Furthermore, the connecting lines, or connectors shown in the various figures presented are intended to represent example functional relationships and/or physical or logical couplings between the various elements, and it should be noted that many alternative or additional functional relationships, physical connections, or logical connections may be present in a practical device.

As used herein, the singular forms “a,” “an,” and “the” are intended to include the plural forms as well, unless the context clearly indicates otherwise.

Operations of all methods described herein may be performed in any suitable order unless otherwise indicated herein or otherwise clearly contradicted by context. The use of any and all examples or exemplary language (e.g., “such as”) provided herein, is intended merely to better illuminate the disclosure and does not pose a limitation on the scope of the disclosure unless otherwise claimed.

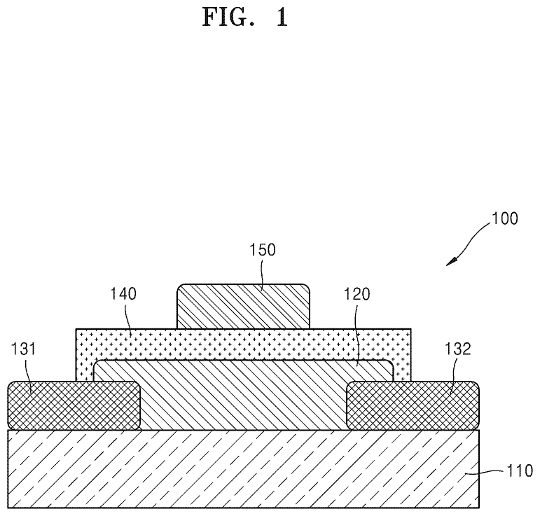

FIG. 1 schematically illustrates a semiconductor device according to an embodiment.

A semiconductor device 100 includes a substrate 110, a channel 120 on the substrate 110, a source electrode 131 electrically connected to one side of the channel 120, a drain electrode 132 electrically connected to the other side of the channel 120, a gate electrode 150 spaced apart from the channel 120, and a gate insulating layer 140 arranged between the channel 120 and the gate electrode 150.

The source electrode 131 may be spaced apart from the drain electrode 132. The channel 120 may extend to a portion of the upper surface of each of the source electrode 131 and the drain electrode 132. The semiconductor device 100 may be applied to a transistor having a planar channel structure.

The substrate 110 may be an insulating substrate or a semiconductor substrate on which an insulating layer is formed. Alternatively, the substrate 110 may be a semiconductor substrate. The semiconductor substrate may include, for example, silicon (Si), germanium (Ge), SiGe, or a group III-V semiconductor material. The substrate 110 may be, for example, a silicon substrate on which silicon oxide (SiO₂) is formed, but is not limited thereto.

The channel 120 may include indium (In), tellurium (Te), and oxygen (O). The channel 120 may be a p-type channel including InₐTe_{b}O_{c} (where, a+b=100, a<50, b>50, and c is less than the chemical stoichiometric value). The channel 120 may have a composition in which oxygen is deficient relative to the chemical stoichiometric value. Chemical stoichiometry describe the quantitative relationships in chemical reactions, and because chemical reactions involve recombination according to formats determined by the reactions of individual molecules within a reaction system, the amount of substances involved in the reactions may have proportional relationships to each other. For example, in a reaction system including In, Te, and O, when a=50 and b=50, the chemical stoichiometric value of O, denoted as c, is 175, and in this case, InₐTe_{b}O_{c} may be stable. For example, when a=25 and b=75, the chemical stoichiometric value of O (c) is 187.5. In an embodiment, the channel 120 may have characteristics of p-type semiconductor oxide with a composition in which a+b=100, a<50, b>50, and c is less than the chemical stoichiometric value. The channel 120 may have an amorphous structure.

The source electrode 131 and the drain electrode 132 may each have a metal material. The source electrode 131 and the drain electrode 132 may include at least one material selected from among tungsten (W), cobalt (Co), nickel (Ni), iron (Fe), titanium (Ti), molybdenum (Mo), chromium (Cr), zirconium (Zr), hafnium (Hf), niobium (Nb), tantalum (Ta), silver (Ag), gold (Au), aluminum (Al), copper (Cu), tin (Sn), vanadium (V), ruthenium (Ru), platinum (Pt), zinc (Zn), and magnesium (Mg). Alternatively, the source electrode 131 and the drain electrode 132 may each be nitride including the above material. The source electrode 131 and the drain electrode 132 may include, for example, at least one of W, titanium nitride (TiN), Mo, molybdenum nitride (MON), Ru, and titanium silicon nitride (TiSiN). The source electrode 131 and the drain electrode 132 may include, for example, Zn with the content of 10 at % or less. Here, the content of Zn may refer to the content of Zn relative to the total metallic elements included in the source electrode 131, excluding O. However, this is only an example, and the content of the source electrode 131 and the drain electrode 132 is not limited thereto.

The gate electrode 150 may include at least one of metal, metal nitride, and transparent conductive oxide (TCO). The gate insulating layer 140 may include oxide including at least one of Hf, Zr, Al, and Si. When the semiconductor device 100 is a component of a memory cell, the gate electrode 150 may be a portion of a word line.

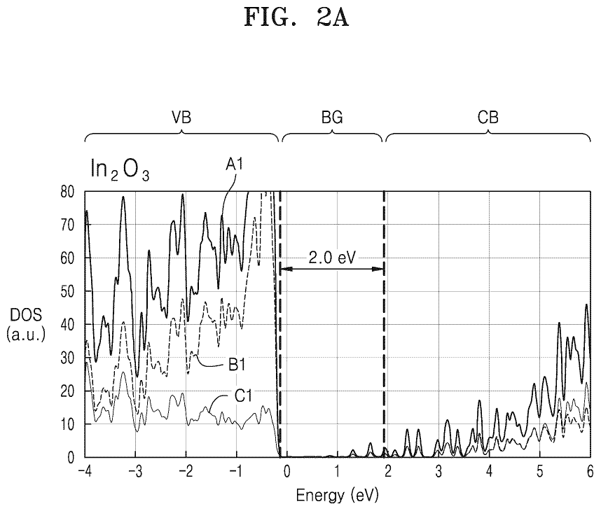

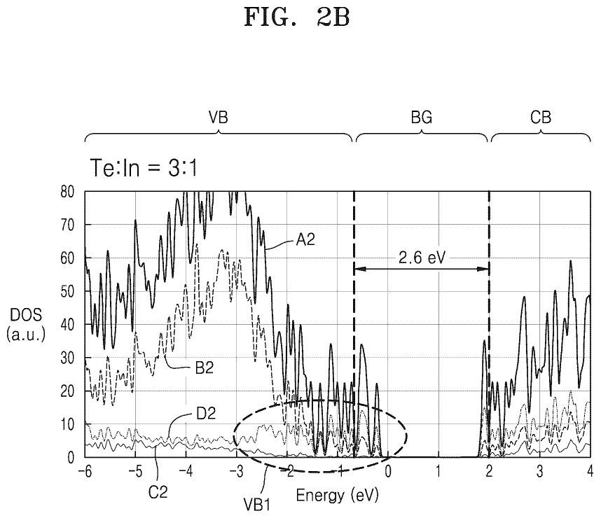

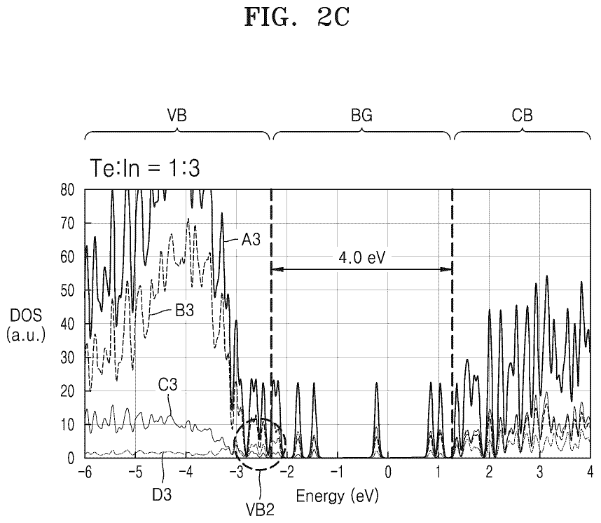

FIGS. 2A to 2C illustrate simulation results for the compositions of the channel.

FIG. 2A illustrates the density of states (DOS) with respect to the energy of indium oxide (In₂O₃), which is a Comparative Example. In₂O₃ is an n-type oxide semiconductor. The DOS represents how many levels exist at a given energy (E). In other words, the DOS refers to the number of energy states per unit volume. The A1 graph shows the DOS for total In₂O₃, the B1 graph shows the DOS for O, and the C1 graph shows the DOS for In. The reference symbols CB, VB, and BG denote the conduction band, valence band, and band gap, respectively. In FIG. 2A, the DOS distribution of O appears relatively high and narrow at the boundary of the valence band. As the DOS distribution is low and wide at the boundary of the valence band, p-type semiconductor characteristics are exhibited more clearly, and as the DOS distribution is low and wide at the boundary of the conduction band, n-type semiconductor characteristics are exhibited more clearly. In this regard, In₂O₃ rarely exhibits p-type semiconductor characteristics, but rather exhibits n-type semiconductor characteristics.

FIG. 2B illustrates the DOS with respect to the energy of indium tellurium oxide having a composition of Te:In=3:1. In this case, the oxygen content has a chemical stoichiometric value of 1.875.

The A2 graph shows the DOS for total indium tellurium oxide, the B2 graph shows the DOS for O, the C2 graph shows the DOS for In, and the D2 graph shows the DOS for Te. At the boundary of the valence band, a region VB1 is observed in which the DOS for In, Te, and O is relatively low and wide. The region VB1 indicates that indium tellurium oxide having a composition of Te:In=3:1 exhibits p-type semiconductor characteristics. In this case, a Te-related shallow state is formed near the Valence Band Maximum (VBM), thereby exhibiting characteristics of a p-type semiconductor doped with holes.

FIG. 2C illustrates the DOS with respect to the energy of indium tellurium oxide having a composition of Te:In=1:3. In this case, the oxygen content is 1.625. In FIG. 2C, indium tellurium oxide may be In₇₅Te₂₅O_{162.5}. The A3 graph shows the DOS for total indium tellurium oxide, the B3 graph shows the DOS for O, the C3 graph shows the DOS for In, and the D3 graph shows the DOS for Te. At the boundary of the valence band, a region VB2, in which the DOS for In, Te, and O is relatively low and wide, appears highly narrow. This indicates that indium tellurium oxide having a composition of Te:In=1:3 rarely exhibits p-type semiconductor characteristics.

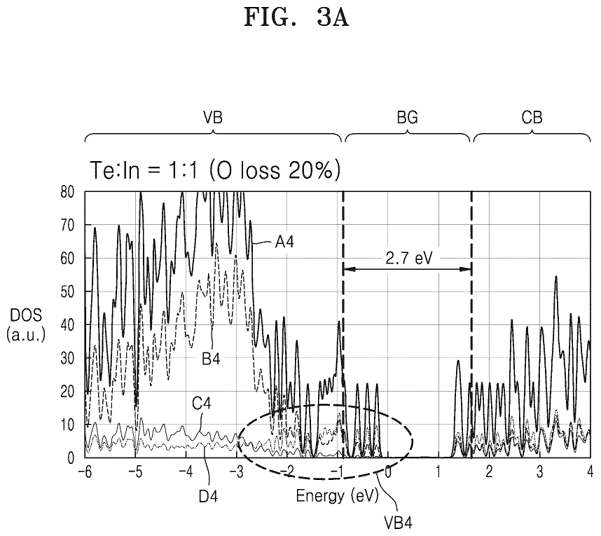

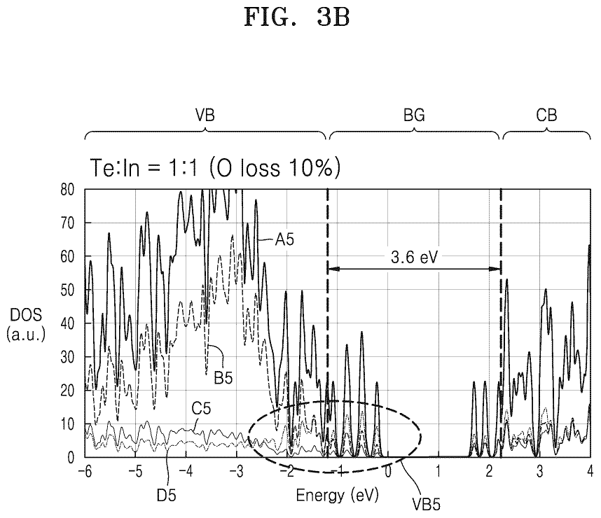

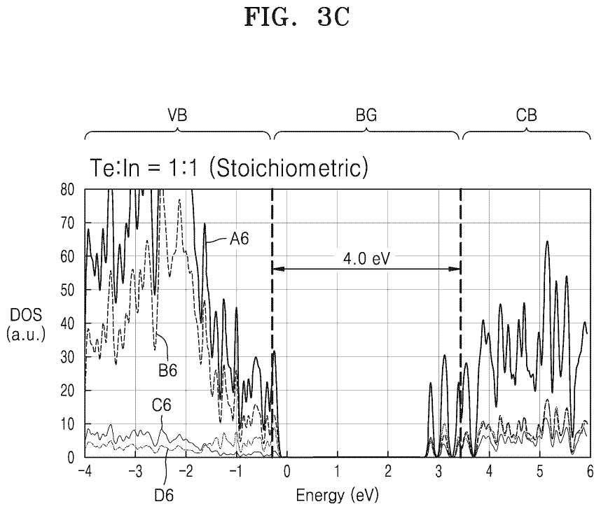

Referring to FIGS. 2B and 2C, the channel 120 of the semiconductor device according to an embodiment may include InₐTe_{b}O_{c} having a composition satisfying a+b=100 and a<b, thereby exhibiting p-type semiconductor characteristics. FIGS. 3A to 3C show the simulation results of changes in the DOS of InₐTe_{b}O_{c}, where a:b=1:1 and c varies. FIGS. 3A to 3C show the simulations of p-type semiconductor characteristics according to the changes in oxygen content.

FIG. 3A illustrates the DOS with respect to energy in a case where the composition has a Te:In ratio of 1:1 and oxygen is deficient by about 20% relative to the chemical stoichiometric value. The deficient amount of O relative to the chemical stoichiometric value is defined as the oxygen vacancy concentration. FIG. 3A illustrates that, when the chemical stoichiometric value of O is 175, the oxygen vacancy concentration is about 20%, and the oxygen content is 140. In FIG. 3A, the A4 graph shows the DOS for total In₅₀Te₅₀O₁₄₀, the B4 graph shows the DOS for O, the C4 graph shows the DOS for In, and the D4 graph shows the DOS for Te. At the boundary of the valence band, a region VB4 is observed in which the DOS for Te, In, and O is low and wide. Referring to FIG. 3A, when O in indium tellurium oxide is about 20% lower than the chemical stoichiometric value, p-type semiconductor characteristics are exhibited.

FIG. 3B illustrates the DOS with respect to energy in a case where the composition has a Te:In ratio of 1:1 and oxygen is deficient by 10% relative to the chemical stoichiometric value. FIG. 3B illustrates that, when the chemical stoichiometric value of O is 175, the oxygen vacancy concentration is about 10%, and the oxygen content is 157.5. In FIG. 3B, the A5 graph shows the DOS for total In₅₀Te₅₀O_{157.5}, the B5 graph shows the DOS for O, the C5 graph shows the DOS for In, and the D5 graph shows the DOS for Te. At the boundary of the conduction band, a region VB5 is observed in which the DOS for Te, In, and O is relatively low and wide. Referring to FIG. 3B, when O in indium tellurium oxide is about 10% lower than the chemical stoichiometric value, p-type semiconductor characteristics are exhibited. Referring to FIGS. 3A and 3B, when the oxygen vacancy concentration is about 20%, relatively greater p-type semiconductor characteristics are exhibited compared to when the oxygen vacancy concentration is about 10%. Therefore, the higher the oxygen vacancy concentration is, the more clearly the p-type semiconductor characteristics may be exhibited. For example, the oxygen vacancy concentration may be in a range of about 5% to about 80%, about 10% to about 70%, or about 10% to about 60%.

FIG. 3C illustrates the DOS with respect to energy in a case where the composition has a Te:In ratio of 1:1 and oxygen has a chemical stoichiometric value. In FIG. 3C, the A6 graph shows the DOS for total In₅₀Te₅₀O₁₇₅, the B6 graph shows the DOS for O, the C6 graph shows the DOS for In, and the D6 graph shows the DOS for Te. In FIG. 3C, at the boundary of the valence band, the DOS for Te, In, and O rarely exhibits p-type semiconductor characteristics. In this regard, the channel 120 of the semiconductor device 100 according to an embodiment may have a composition in which oxygen is deficient relative to the chemical stoichiometric value.

As described above, referring to FIGS. 2A to 3C, the channel 120 may exhibit p-type semiconductor characteristics by including InₐTe_{b}O_{c} (where, a+b=100, a<50, b>50, and c is less than the chemical stoichiometric value). For example, c<187.5, c<180, or c<175.

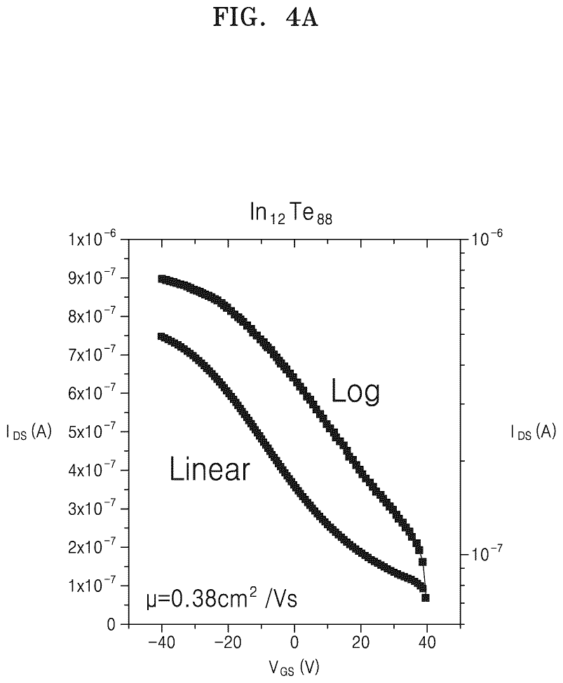

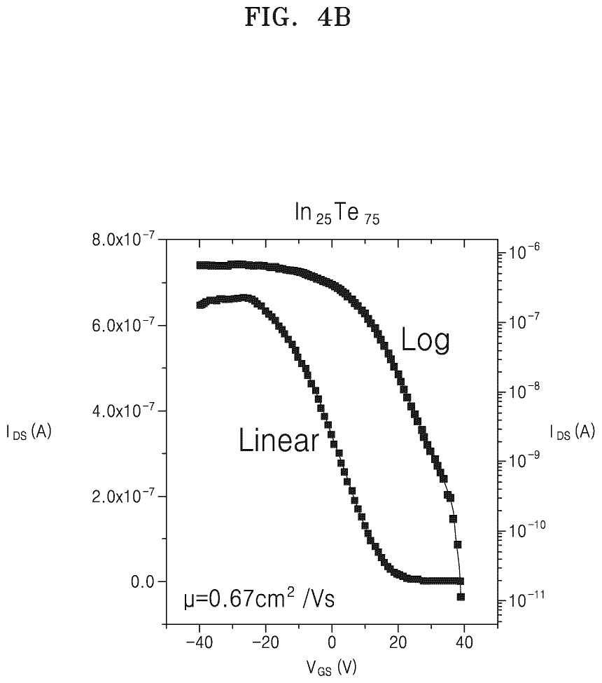

FIGS. 4A and 4B show voltage-current graphs of a semiconductor device according to an embodiment.

FIG. 4A illustrates the voltage-current characteristics of a semiconductor device including an In₁₂Te₈₈ channel, and when Ves has a negative value, on-current is observed, and thus, p-type semiconductor characteristics are exhibited. The graph indicates both a linear scale and a log scale.

FIG. 4B illustrates the voltage-current characteristics of a semiconductor device including an In₂₅Te₇₅ channel, and when Ves has a negative value, on-current is observed, and thus, p-type semiconductor characteristics are exhibited. Referring to FIGS. 4A and 4B, the channel 120 of the semiconductor device according to an embodiment may include InₐTe_{b}O_{c} having a composition satisfying a+b=100 and a<b, thereby exhibiting p-type semiconductor characteristics. The composition of InₐTe_{b} in the channel 120 may satisfy 10≤a<50, 12≤a≤40, and 50<b≤90 or 60≤b≤88. The ratio of b to a (b/a) may be greater than 1 but not more than 7.

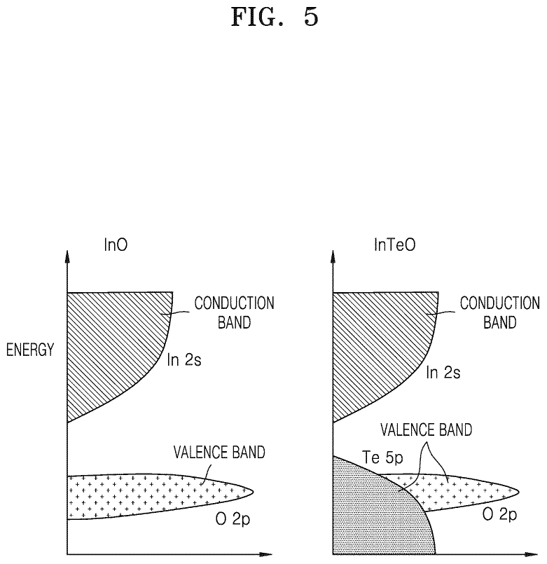

FIG. 5 schematically illustrates energy band diagrams of indium oxide and indium tellurium oxide, comparing the n-type characteristics of indium oxide with the p-type characteristics of indium tellurium oxide.

The energy band diagrams include both the conduction band and the valence band, and the Conduction Band Minimum (CBM) of indium oxide includes 2s orbitals of In ions, whereas the VBM may mainly include 2p orbitals of O ions having strong directionality and high electronegativity. The VBM of In₂O₃ may have a small band dispersion and a deep energy level. This feature makes it difficult to dope indium oxide with holes and to achieve high hole mobility, and may hinder the p-type channel operation of a transistor. Band dispersion engineering for positioning orbitals with low anisotropy at the VBM may be employed to increase hole mobility.

The VBM of indium tellurium oxide may include 2p orbitals of O ions and 5p orbitals of Te ions. Because the VBM of indium tellurium oxide may have a wide band dispersion and a low energy level, high hole mobility may be achieved, which enables the p-type channel operation of a transistor. Therefore, a semiconductor device according to an embodiment may implement a p-type channel including indium tellurium oxide.

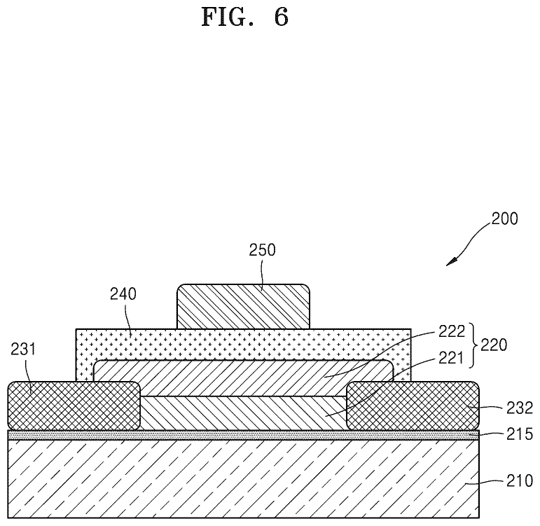

FIG. 6 schematically illustrates a semiconductor device according to another embodiment.

Referring to FIG. 6, a semiconductor device 200 includes a substrate 210, a channel 220 on the substrate 210, a source electrode 231 electrically connected to one side of the channel 220, a drain electrode 232 electrically connected to the other side of the channel 220, a gate electrode 250 spaced apart from the channel 220, and a gate insulating layer 240 arranged between the channel 220 and the gate electrode 250. The channel 220 may include an n-type first channel 221 and a p-type second channel 222 disposed on the n-type first channel 221. FIG. 6 illustrates that the p-type second channel 222 is positioned on the n-type first channel 221, but the positions of the n-type first channel 221 and the p-type second channel 222 may be interchanged.

The source electrode 231 and the drain electrode 232 may each be electrically connected to the n-type first channel 221 and the p-type second channel 222. The p-type second channel 222 may extend to a portion of the upper surface of each of the source electrode 231 and the drain electrode 232. A buffer layer 215 may be further arranged between the substrate 210 and the channel 220.

The n-type first channel 221 may include at least one of In, Zn, Sn, Ga, and Hf. The n-type first channel 221 may include, for example, zinc indium oxide (ZIO), indium gallium oxide (IGO), or indium gallium zinc oxide (IGZO). The n-type first channel 221 may include InGaZnO, ZrInZnO, InGaZnO₄, ZnInO, In₂O₃, HfInZnO, or a combination thereof.

The p-type second channel 222 may include In, Te, and O. The p-type second channel 222 may include InₐTe_{b}O_{c} (where, a+b=100, a<50, b>50, and c is less than the chemical stoichiometric value). For example, the p-type second channel 222 may be configured to satisfy 10≤a<50, 12≤a≤40, and 50<b≤90 or 60≤b≤88. The p-type second channel 222 may have a composition in which oxygen is deficient relative to the chemical stoichiometric value. For example, c<187.5, c<180, or c<175.

The p-type second channel 222 may have substantially the same configuration and operation as the channel 120 described above with reference to FIG. 1.

The semiconductor device 200 may include the n-type first channel 221 and the p-type second channel 222 and thus be applied to an ambipolar transistor.

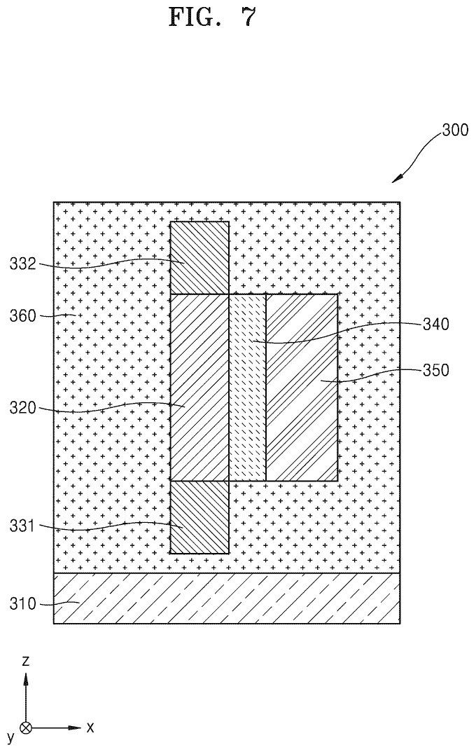

FIG. 7 schematically illustrates a semiconductor device according to another embodiment.

Referring to FIG. 7, a semiconductor device 300 includes a substrate 310, a source electrode 331 on the substrate 310, a drain electrode 332 spaced apart from the source electrode 331, and a channel 320 between the source electrode 331 and the drain electrode 332.

The channel 320 may include InₐTe_{b}O_{c} (where, a+b=100, a<50, b>50, and c<175) and operate as a p-type channel.

The source electrode 331 may be spaced apart from the drain electrode 332 in a direction perpendicular to the substrate 310 (the Z direction), and the source electrode 331, the channel 320, and the drain electrode 332 may be arranged in series in the direction perpendicular to the substrate 310 (the Z direction). The source electrode 331, the channel 320, and the drain electrode 332 may be sequentially arranged without any intervening layers therebetween. The source electrode 331, the channel 320, and the drain electrode 332 may have the same width. The channel 320 may be arranged such that the lengthwise direction thereof may be in the direction perpendicular to the substrate 310 (Z direction). In the present specification, the lengthwise direction refers to the direction in which the length of a component is great as viewed in a drawing. The semiconductor device 300 may be applied to a vertical channel transistor.

The gate electrode 350 may be provided on one side of the channel 320. A gate insulating layer 340 may be provided between the channel 320 and the gate electrode 350. The gate electrode 350 may be arranged such that the lengthwise direction thereof (Z direction) is perpendicular to the substrate 310. The channel 320, the gate insulating layer 340, and the gate electrode 350 may be arranged in series in the horizontal direction (X direction) relative to the substrate 310. A mold insulating layer 360 may be provided on the substrate 310 to fill the void. The source electrode 331 may be spaced apart from the substrate 310 by the mold insulating layer 360.

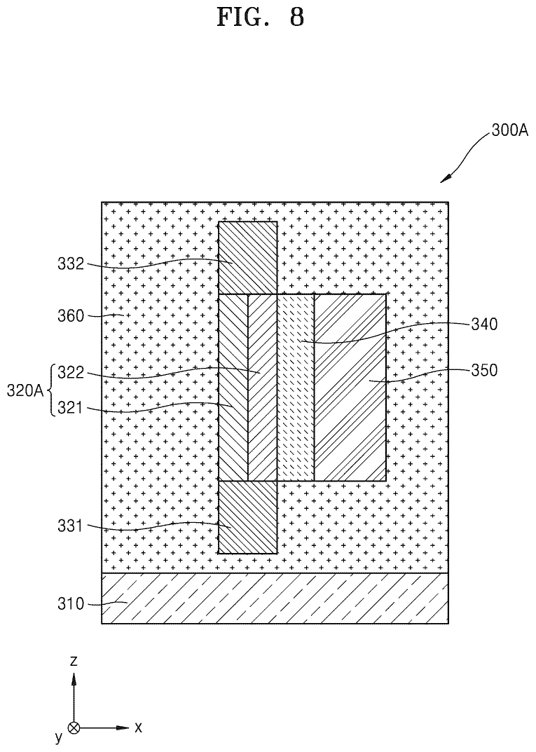

FIG. 8 illustrates an example in which the channel is changed, compared to FIG. 7. In FIG. 8, components using the same reference symbols as those in FIG. 7 may have substantially the same configuration and operation, and thus, detailed descriptions thereof are omitted.

A semiconductor device 300A may include a channel 320A including two layers. The channel 320A may include an n-type first channel 321 and a p-type second channel 322 disposed on the n-type first channel 321. The n-type first channel 321 and the p-type second channel 322 may be arranged in series in the direction perpendicular to the substrate 310 (Z direction). The n-type first channel 321 may include at least one of In, Zn, Sn, Ga, and Hf. The n-type first channel 321 may include, for example, InGaZnO, ZrInZnO, InGaZnO₄, ZnInO, In₂O₃, HfInZnO, or any combination thereof. The n-type first channel 321 may include, for example, In and Zn, and the content of In in the n-type first channel 321 may be greater than or equal to the content of Zn. The thickness of the n-type first channel 321 may be about 1 nm or greater, about 3 nm or greater, about 20 nm or less, about 15 nm or less, or about 10 nm or less.

The p-type second channel 320 may include InₐTe_{b}O_{c} (where, a+b=100, a<50, b>50, and c is less than the chemical stoichiometric value). In the composition, a is at least 10 but less than 50 or at least 12 but less than 40, and b is greater than 50 but not more than 90 or greater than 60 but not more than 88. The p-type second channel 320 may have a composition in which oxygen is deficient relative to the chemical stoichiometric value. For example, c<187.5, c<180, or c<175.

The semiconductor device 300A may include the n-type first channel 321 and the p-type second channel 322 and thus exhibit ambipolar characteristics. Accordingly, an ambipolar transistor may be implemented using multiple channels.

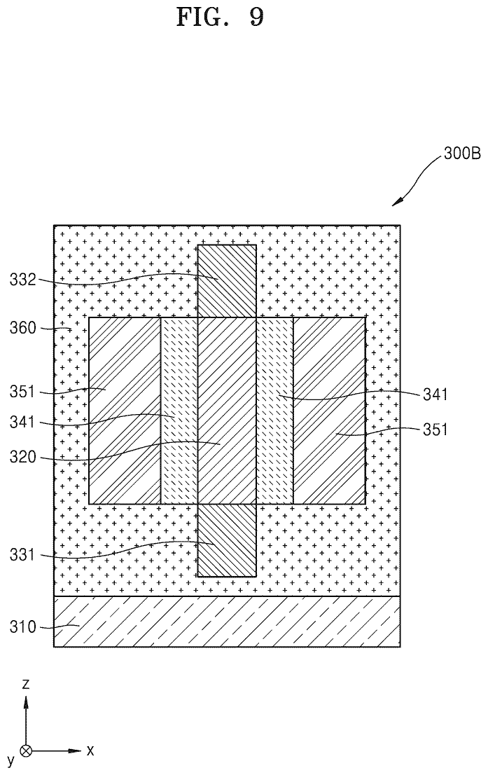

FIG. 9 illustrates a semiconductor device according to another embodiment. In FIG. 9, components using the same reference symbols as those in FIG. 7 may have substantially the same configuration and effects, and thus, detailed descriptions thereof are omitted.

A semiconductor device 300B includes a source electrode 331, a channel 320, and a drain electrode 332, which are arranged in the direction perpendicular to a substrate 310 (Z direction). A gate insulating layer 341 may be disposed around the periphery of the channel 320, and a gate electrode 351 may be disposed around the periphery of the gate insulating layer 341. As the gate electrode 351 is disposed around the periphery of the channel 320, the area where the gate electrode 351 faces the channel 320 may be increased so that short-channel effects may be improved. The semiconductor device 300B may be applied to a Gate-All-Around (GAA) transistor.

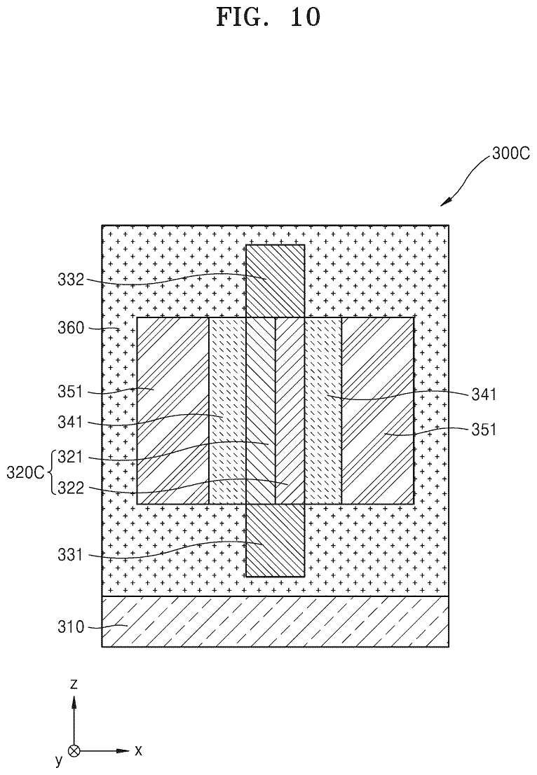

FIG. 10 illustrates an example in which the channel is changed, compared to FIG. 9. A semiconductor device 300C may include a channel 320C including two layers. The channel 320C may include the n-type first channel 321 and the p-type second channel 322 disposed on the n-type first channel 321. Because the n-type first channel 321 and the p-type second channel 322 are the same as those described with reference to FIG. 8, the detailed descriptions thereof are omitted.

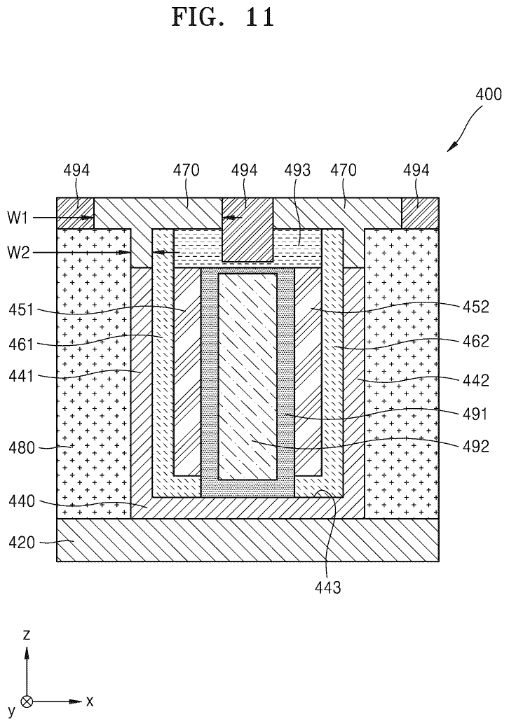

FIG. 11 schematically illustrates a semiconductor device according to another embodiment.

Referring to FIG. 11, a semiconductor device 400 may include a source electrode 420 and a channel 440 disposed on the source electrode 420. The channel 440 may include InₐTe_{b}O_{c} (where, a+b=100, a<50, b>50, and c is less than the chemical stoichiometric value). In the composition, a is at least 10 but less than 50 or at least 12 but less than 40, and b is greater than 50 but not more than 90 or greater than 60 but not more than 88. The channel 440 may have a composition in which oxygen is deficient relative to the chemical stoichiometric value. For example, c<187.5, c<180, or c<175.

The channel 440 may have a U-shaped cross-section. The channel 440 may include a bottom portion 443 connected to the source electrode 420, a first vertical extension 441 extending from one end of the bottom portion 443 in a direction perpendicular to the source electrode 420 (Z direction), and a second vertical extension 442 extending from the other end of the bottom portion 443 in the direction perpendicular to the source electrode 420 (Z direction).

A first gate electrode 451 may be spaced apart from the first vertical extension 441, and a second gate electrode 452 may be spaced apart from the second vertical extension 442. A first gate insulating layer 461 may be disposed between the first vertical extension 441 and the first gate electrode 451, and a second gate insulating layer 462 may be disposed between the second vertical extension 442 and the second gate electrode 452.

At least one of the first gate electrode 451 and the second gate electrode 452 may extend in a second horizontal direction y. The first gate electrode 451 may be spaced apart from the second gate electrode 452. At least one of the first gate electrode 451 and the second gate electrode 452 may form a word line WL. The electrical signal that is input to the first gate electrode 451 may differ from that input to the second gate electrode 452. The first gate electrode 451 may be configured to control the first vertical extension 441 of the channel 440, and the second gate electrode 452 may be configured to control the second vertical extension 442 of the channel 440.

An insulating liner 491 may be arranged between the first gate electrode 451 and the second gate electrode 452 that are spaced apart from each other. The insulating liner 491 may be conformally arranged on the sidewalls of the first gate electrode 451 and the second gate electrode 452, which face each other, and/or on an upper surface of the channel 440. The insulating liner 491 may have the upper surface arranged on the same plane as the first gate electrode 451 and the second gate electrode 452. The insulating liner 491 may include, for example, silicon nitride (SiNx). A buried insulating layer 492 may fill the space between the first gate electrode 451 and the second gate electrode 452 that are spaced apart from each other on the insulating liner 491. The buried insulating layer 492 may include, for example, SiO₂. An upper insulating layer 493 may be arranged on upper surfaces of the first gate electrode 451, the second gate electrode 452, and/or the buried insulating layer 492. An upper surface of the upper insulating layer 493 may be at the same level as an upper surface of the mold insulating layer 480.

A drain electrode 470 may be arranged on the channel 440. The drain electrode 470 may serve as a landing pad. The drain electrode 470 may include a left drain electrode and a right drain electrode. The left drain electrode 470 may be electrically connected to the first vertical extension 441. The right drain electrode 470 may be electrically connected to the second vertical extension 442. The left drain electrode may not be electrically connected to the right drain electrode. The drain electrode 470 may include an upper portion and a lower portion. The upper portion of the drain electrode 470 may be a portion of the drain electrode 470 that is at a higher level than the upper surface of the mold insulating layer 480. The lower portion of the drain electrode 470 may be a portion of the drain electrode 470 that is located within a drain electrode recess defined between the mold insulating layer 480 and the upper insulating layer 493. In an embodiment, the upper portion of the drain electrode 470 may have a first width W1 in a first horizontal direction x, and the lower portion of the drain electrode 470 may have a second width W2 that is less than the first width W1 in the first horizontal direction x. The lower portion of the drain electrode 470 may be arranged within the drain electrode recess, and the upper portion of the drain electrode 470 may have, on the lower portion of the drain electrode 470, a bottom surface arranged on the upper surface of the mold insulating layer 480 and the upper surface of the upper insulating layer 493; thus, the drain electrode 470 may have a T-shaped vertical cross-section. The bottom surface of the lower portion of the drain electrode 470 may be in contact with an upper surface of the first vertical extension 441 and/or an upper surface of the second vertical extension 442. Both sidewalls of the lower portion of the drain electrode 470 may be aligned with both sidewalls of the first vertical extension 441 and the second vertical extension 442. The bottom surface of the lower portion of the drain electrode 470 may be at a higher level than the upper surface of the first gate electrode 451 and/or the second gate electrode 452, and a portion of the sidewall of the lower portion of the drain electrode 470 may be covered by the first gate insulating layer 461 and/or the second gate insulating layer 462. A drain electrode insulating layer 494 surrounding the drain electrode 470 may be arranged on the upper surfaces of the mold insulating layer 480 and the upper insulating layer 493. The semiconductor device 400 may have a Vertical Channel Structure (VCT) including a vertical channel area where the channel 440 extends from the source electrode 420 in the vertical direction Z.

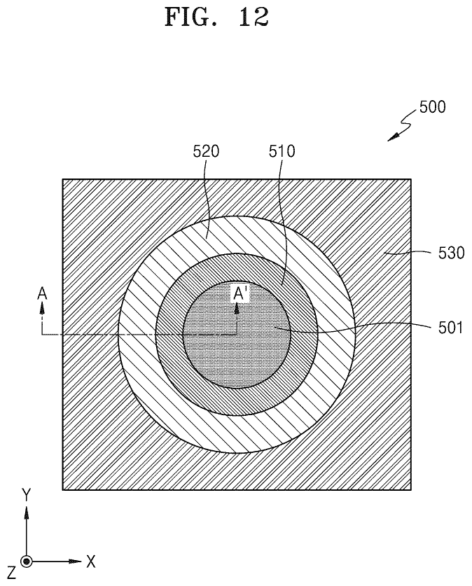

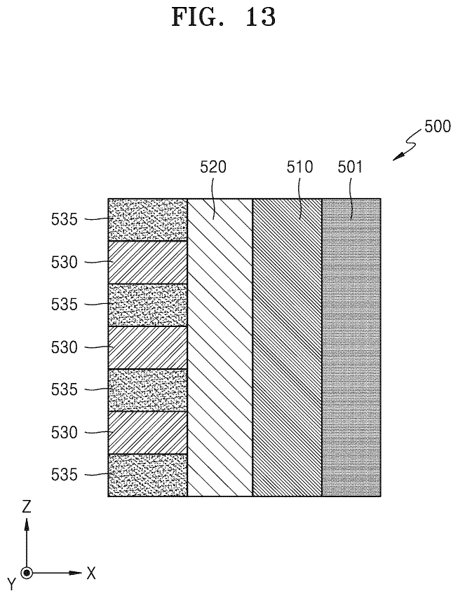

FIGS. 12 and 13 respectively are a horizontal cross-sectional view and a vertical cross-sectional view schematically illustrating structures of memory cell strings of a memory device, according to an embodiment. Referring to FIG. 12, a memory cell string of a memory device 500 according to an embodiment may include a center filler 501, a channel 510, a ferroelectric layer 520, and a gate electrode 530, which are concentrically arranged in the XY plane. The channel 510 may include InaTeOc (where, a+b=100, a<50, b>50, and c is less than the chemical stoichiometric value). In the composition, a is at least 10 but less than 50 or at least 12 but less than 40, and b is greater than 50 but not more than 90 or greater than 60 but not more than 88. The channel 510 may have a composition in which oxygen is deficient relative to the chemical stoichiometric value.

The channel 510 may be arranged to surround the center filler 501, the ferroelectric layer 520 may be arranged to surround the channel 510, and the gate electrode 530 may be arranged to surround the ferroelectric layer 520. The ferroelectric layer 520 may include an interface region 525 in a region near the channel 510. The center filler 501 may serve to support the channel 510 and the memory cell string by filling the space on the inner sidewall of the channel 510. However, the center filler 501 may not be essential and may be omitted. In this case, a void may exist instead of the center filler 501.

FIG. 13 is a schematic cross-sectional view, taken along a line A-A′ of FIG. 12 in a first direction (that is, the Z-axis direction) from the center of the center filler 501 to the gate electrode 530. Referring to FIG. 13, the memory device 500 may include a plurality of gate electrodes 530 that are spaced apart from each other in the first direction. Spacers 535 may be arranged between the gate electrodes 530. In other words, the gate electrodes 530 and the spacers 535 may be alternately arranged in the first direction. The memory device 500 may include: the channel 510 that faces and is spaced apart from the gate electrodes 530 and the spacers 535 in the second direction perpendicular to the first direction (that is, the X-axis direction) and consecutively extends in the first direction; and the ferroelectric layer 520 that consecutively extends in the first direction and is arranged between the channel 510 and the gate electrodes 530. In addition, the memory device 500 may further include the center filler 501 that consecutively extend on the inner side of the channel 510 in the first direction. In other words, the ferroelectric layer 520, the channel 510, and the center filler 501 may be sequentially arranged in the second direction from the gate electrodes 530 and the spacers 535. Each spacer 535 may include SiO₂ that is insulating, but is not limited thereto.

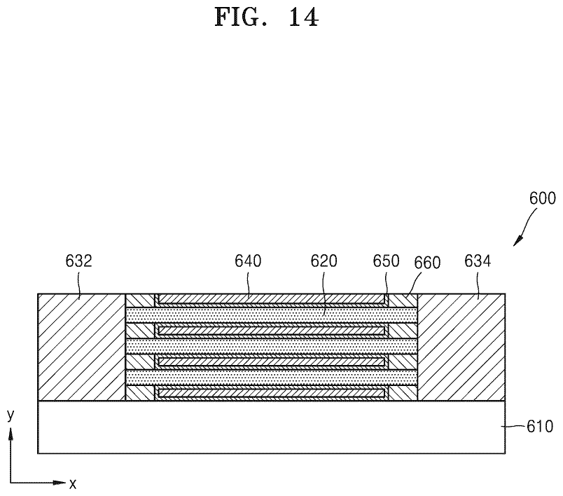

FIG. 14 illustrates a semiconductor device 600 according to an embodiment. The semiconductor device 600 includes a plurality of channels 620 disposed on a substrate 610, a source electrode 632 and a drain electrode 634 that are in contact with the channels 620, and a plurality of gate electrodes 640 that are spaced apart from the channels 620. The channels 620 may include InₐTe_{b}O_{c} (where, a+b=100, a<50, b>50, and c is less than the chemical stoichiometric value). In the composition, a is at least 10 but less than 50 or at least 12 but less than 40, and b is greater than 50 but not more than 90 or greater than 60 but not more than 88. The channels 620 may have a composition in which oxygen is deficient relative to the chemical stoichiometric value.

The substrate 610 may be an insulating substrate or a semiconductor substrate on which an insulating layer is formed. The semiconductor substrate may include, for example, Si, Ge, SiGe, or the like. The substrate 610 may be, for example, a silicon substrate on which SiO₂ is formed, but is not limited thereto.

On the substrate 610, the source electrode 632 and the drain electrode 634 may be spaced apart from each other the first direction (the X direction), and the channels 620 may be spaced apart from each other between the source electrode 632 and the drain electrode 634 in the second direction (the Y direction).

The gate electrodes 640 may be respectively spaced apart from the channels 620, and a ferroelectric layer 650 may be arranged between the gate electrode 640 and the channel 620. For example, the ferroelectric layer 650 may be arranged to surround at least a portion of the gate electrode 640. For example, the gate electrodes 640 and the channels 620 may be alternately arranged in the second direction (the Y direction), and the ferroelectric layer 650 may surround the gate electrode 640. The ferroelectric layer 650 may insulate the channel 620 from the gate electrode 640 and suppress a leakage current.

The contact between each channel 620 and the source electrode 632 and the drain electrode 634 may take the form of an edge contact. For example, both ends of the channel 620 may contact the source electrode 632 and the drain electrode 634, respectively.

Each gate electrode 640 may be spaced apart from the source electrode 632 and the drain electrode 634, and spacers 660 may be further arranged between the gate electrode 640 and the source electrode 632 and between the gate electrode 640 and the drain electrode 634. Because the source electrode 632, the gate electrode 640, and the drain electrode 634 are arranged in the first direction (the X direction), parasitic capacitances may be generated between the source electrode 632 and the gate electrode 640 and between the gate electrode 640 and the drain electrode 634. To reduce the parasitic capacitances, the spacers 660 may include, for example, a boron nitride layer. Because the boron nitride layer does not have porosity and has mechanical strength, the boron nitride layer may securely support the channels 620 arranged on the spacers 660.

The semiconductor device 600 may have a multi-bridge structure in which both ends of each channel 620 are in contact with the source electrode 632 and the drain electrode 634 and stacked apart from each other in a direction away from the substrate 610. The channel having the multi-bridge structure may reduce short-channel effects and the area occupied by the source electrode and the drain electrode, providing an advantage for high integration. In addition, because the source/drain junction capacitance may be uniformly maintained regardless of the positions of channels, the semiconductor device 600 may be applicable as a high-speed and high-reliability device. The semiconductor device 600 may be applied to a so-called GAA transistor. The semiconductor device 600 may be applied as, for example, a logic device or a memory device.

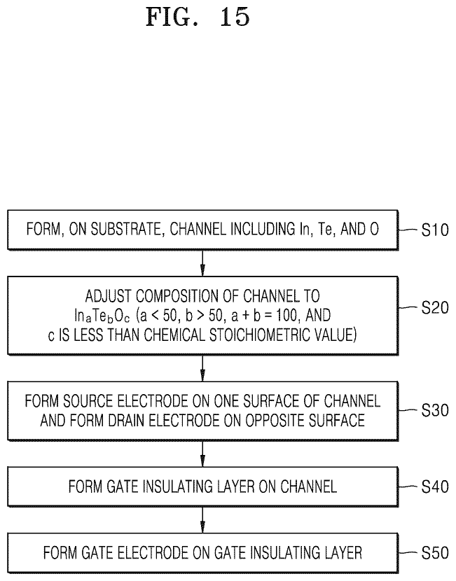

FIG. 15 is a flowchart of a method of manufacturing a semiconductor device, according to an embodiment.

Referring to FIG. 15, the method of manufacturing a semiconductor device includes operation S10 of forming, on a substrate, a channel including In, Te, and O. The forming of the channel may be implemented according to a Physical Vapor Deposition (PVD) method, a Chemical Vapor Deposition (CVD) method, or an Atomic Layer Deposition (ALD) method. In operation S20, the composition of the channel is adjusted to InₐTe_{b}O_{c} (a<50, b>50, a+b=100, and c is less than the chemical stoichiometric value). In the composition, a is at least 10 but less than 50 or at least 12 but less than 40, and b is greater than 50 but not more than 90 or greater than 60 but not more than 88. The channel may have a composition in which oxygen is deficient relative to the chemical stoichiometric value. For example, c<187.5, c<180, or c<175.

In operation S30, a source electrode is formed on one surface of the channel, and a drain electrode is formed on the opposite surface. In operation S40, a gate insulating layer is formed on the channel. In operation S50, a gate electrode is formed on the gate insulating layer. As a result, a semiconductor device including a p-type channel may be manufactured.

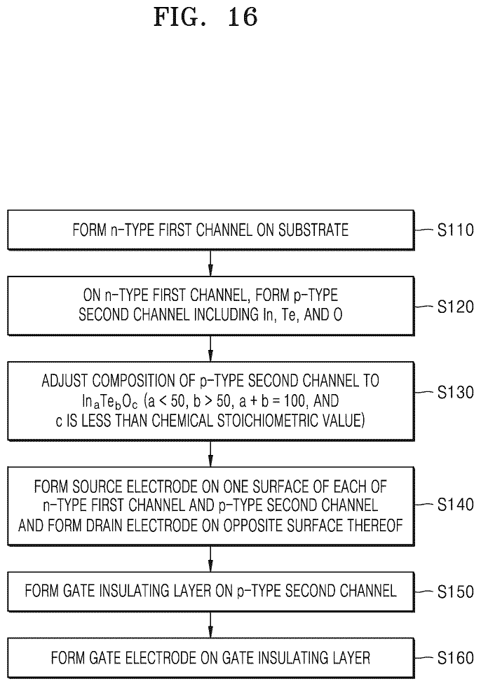

FIG. 16 is a flowchart of a method of manufacturing a semiconductor device, according to another embodiment.

Referring to FIG. 16, the method of manufacturing a semiconductor device includes operation S110 of forming an n-type first channel on a substrate. The n-type first channel may include at least one of In, Zn, Sn, Ga, and Hf. In operation S120, a p-type second channel is formed on the n-type first channel. The method of forming the n-type first channel and the p-type second channel may be implemented according to a PVD method, a CVD method, or an ALD method.

The p-type second channel includes In, Te, and O. In operation S130, the composition of the p-type second channel is adjusted to InₐTe_{b}O_{c} (a<50, b>50, a+b=100, and c is less than the chemical stoichiometric value). In the composition, a is at least 10 but less than 50 or at least 12 but less than 40, and b is greater than 50 but not more than 90 or greater than 60 but not more than 88. The channel may have a composition in which oxygen is deficient relative to the chemical stoichiometric value.

In operation S140, a source electrode is formed on one surface of each of the n-type first channel and the p-type second channel, and a drain electrode is formed on the opposite surface thereof. For example, the source electrode may be formed on a first end region of the each of the n-type first channel and the p-type second channel and the drain electrode may be formed on a second end region of each of the n-type first channel and the p-type second channel, the first end region and the second end region may be opposite each other. In operation S150, a gate insulating layer is formed on the p-type second channel. In operation S160, a gate electrode is formed on the gate insulating layer. Accordingly, a semiconductor device including an ambipolar channel may be manufactured.

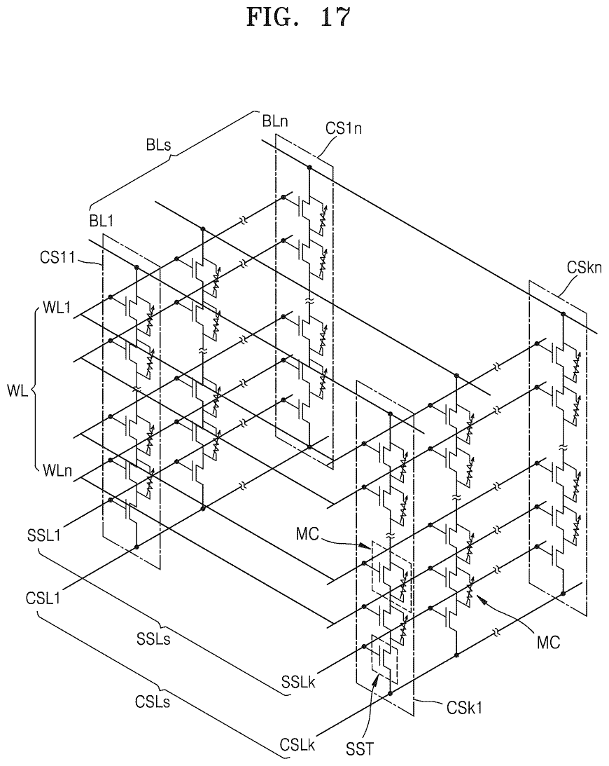

FIG. 17 illustrates an equivalent circuit of a memory device according to an embodiment.

Referring to FIG. 17, the memory device may include a plurality of memory cell strings CS11 to CSkn. The memory cell strings CS11 to CSkn may be two-dimensionally arranged along the row direction and the column direction, thereby forming rows and columns. Each of the memory cell strings CS11 to CSkn may include a plurality of memory cells MC and a plurality of string selection transistors SST. The memory cells MC and the string selection transistors SST of each of the memory cell strings CS11 to CSkn may be stacked in a height direction. The memory cells MC in each of the memory cell strings CS11 to CSkn may correspond to circuits where transistors and resistors are connected in parallel. For example, each of the memory cell strings CS11 to CSkn may be the memory cell string shown in FIGS. 12 and 13.

Rows of the memory cell strings CS11 to CSkn may be respectively connected to different string selection lines SSL1 to SSLk. For example, the string selection transistors SST of the memory cell strings CS11 to CSkn may be commonly connected to the string selection line SSL1. The string selection transistors SST of the memory cell strings CS11 to CSkn may be commonly connected to the string selection line SSLk.

In addition, columns of the memory cell strings CS11 to CSkn may be respectively connected to bit lines BL1 to BLn. For example, memory cells MC and string selection transistors SST of the memory cell strings CS11 to CSk1 may be commonly connected to the bit line BL1, and the memory cells MC and the string selection transistors SST of the cell strings CSIn to CSkn may be commonly connected to the bit line BLn.

In addition, rows of the memory cell strings CS11 to CSkn may be respectively connected to common source lines CSL1 to CSLk. For example, the string selection transistors SST of the memory cell strings CS11 to CSIn may be commonly connected to the common source line CSL1, and the string selection transistors SST of the memory cell strings CSk1 to CSkn may be commonly connected to the common source line CSLk.

Memory cells MC, which are at the same height from the substrate (or the string selection transistors SST), may be commonly connected to one word line WL, and the memory cells MC at different heights may be respectively connected to different word lines WL1 to WLm.

In this configuration, writing and reading operations may be performed in units of rows of the memory cell strings CS11 to CSkn. For example, the memory cell strings CS11 to CSkn may be selected in units of one row by the common source lines CSLs, and the memory cell strings CS11 to CSkn may be selected in units of one row by the string selection lines SSLs. In the selected row of the memory cell strings CS11 to CSkn, writing and reading operations may be performed in units of pages. For example, the page may be one row of memory cells MC connected to a single word line WL. In the selected row of the memory cell strings CS11 to CSkn, the memory cells MC may be selected by the word lines WL in units of pages.

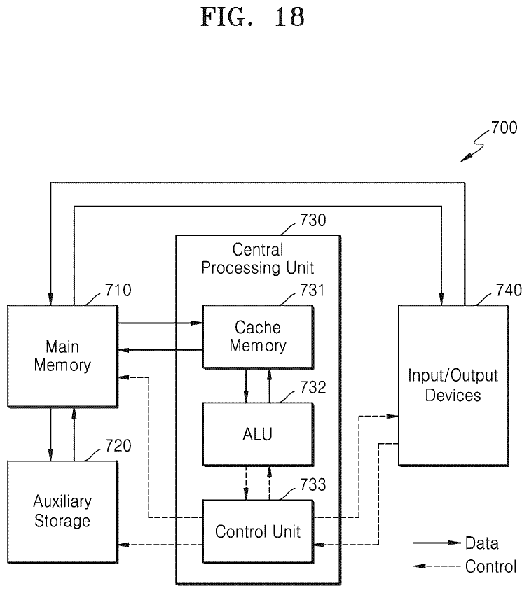

The semiconductor device 100, 200, 300, 300A, 300B, 300C, 400, 500, and 600 according to an embodiment may be used to store data in various electronic apparatuses. FIG. 18 is a schematic conceptual view of a device architecture that may be applied to an electronic apparatus, according to embodiments. Referring to FIG. 18, an electronic apparatus 700 may include a main memory 710, an auxiliary storage 720, a Central Processing Unit (CPU) 730, and input/output devices 740. The CPU 730 may include a cache memory 731, an Arithmetic Logic Unit (ALU) 732, and a control unit 733. The cache memory 731 may include static random access memory (SRAM). The main memory 710 may include a Dynamic Random Access Memory (DRAM) device, and the auxiliary storage 720 may include the semiconductor devices 100, 200, 300, 300A, 300B, 300C, 400, 500, and 600 according to an embodiment. Alternatively, all of the cache memory 731, the main memory 710, and the auxiliary storage 720 may include the semiconductor devices 100, 200, 300, 300A, 300B, 300C, 400, 500, and 600 according to an embodiment. In some cases, the electronic apparatus 700 may be implemented such that computing unit devices are close to memory unit devices in a single chip, without the need for distinguishing between the sub-units described above.

Some of the above-described elements and/or functional blocks may be implemented as: processing circuitry, such as hardware including a logic circuit; a combination of hardware and software, such as processor-executed software; or a combination thereof. For example, the processing circuitry may include a CPU, an ALU, a digital signal processor, a microcomputer, a Field Programmable Gate Array (FPGA), a System-on-Chip (SoC), a programmable logic unit, a microprocessor, an Application-Specific Integrated Circuit (ASIC), or the like. The processing circuitry may include electronic components, such as at least one of a transistor, a resistor, and a capacitor. The processing circuitry may include electronic components, such as at least one logic gate selected from an AND gate, an OR gate, a NAND gate, and a NOR gate.

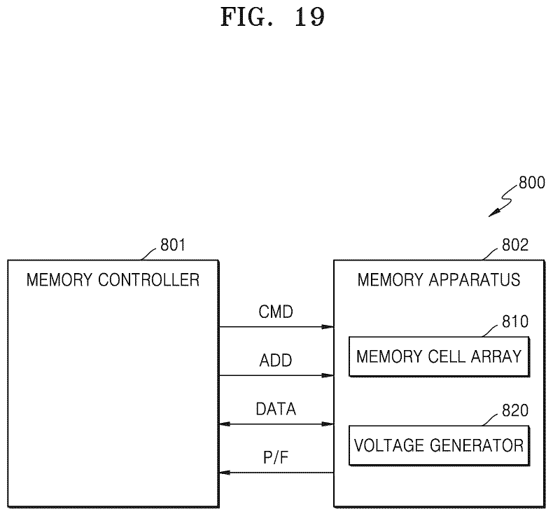

FIG. 19 is a block diagram of a memory system 800 according to an embodiment.

Referring to FIG. 19, the memory system 800 may include a memory controller 801 and a memory apparatus 802. The memory controller 801 performs control operations on the memory apparatus 802, and for example, the memory controller 801 provides the memory apparatus 802 with addresses ADD and commands CMD for performing a programming (or recording) operation, a read operation, and/or an erasing operation on the memory apparatus 802. In addition, data for the programming operation and the reading may be transmitted between the memory controller 801 and the memory apparatus 802.

The memory apparatus 802 may include a memory cell array 810 and a voltage generator 820. The memory cell array 810 may include a plurality of memory cells and also include the above-described semiconductor devices 100, 200, 300, 300A, 300B, 300C, 400, 500, and 600 according to an embodiment.

The memory controller 801 may include: processing circuitry, such as hardware including a logic circuit; a combination of hardware and software, such as processor-executed software; or a combination thereof. For example, the processing circuitry may more specifically include a CPU, an ALU, a digital signal processor, a microcomputer, an FPGA, an SoC, a programmable logic unit, a microprocessor, or an ASIC, but is not limited thereto. The memory controller 801 may operate in response to a request from a host (not shown) and may be configured to convert the memory controller 801 into a special-purpose controller by accessing the memory apparatus 802 and controlling the control operations (e.g., the recording/reading operations) described above. The memory controller 801 may generate addresses ADD and commands CMD for performing programming/reading/erasing operations on the memory cell array 810. In addition, in response to a command from the memory controller 801, the voltage generator 820 (e.g., a power circuit) may generate voltage control signals to control voltage levels of word lines for data programming or data reading.

In addition, the memory controller 801 may perform a determination operation on the data that is read from the memory apparatus 802. For example, the number of on-cells and/or off-cells may be determined based on the data that is read from the memory cell. The memory apparatus 802 may provide pass/fail signals P/F to the memory controller 801, based on the result of reading the read data. The memory controller 801 may control the writing and reading operations of the memory cell array 410 in response to the pass/fail signals P/F.

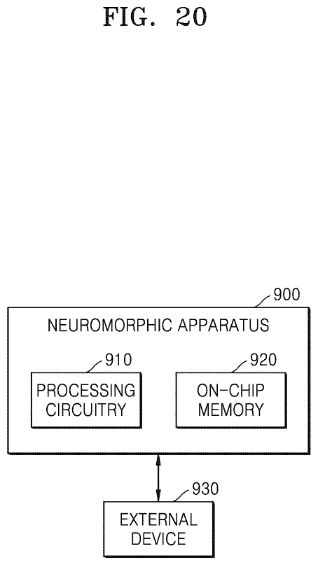

FIG. 20 is a block diagram of a neuromorphic apparatus 900 and an external device 930 connected thereto, according to an embodiment.

Referring to FIG. 20, the neuromorphic apparatus 900 may include processing circuitry 910 and/or an on-chip memory 920. The on-chip memory 920 may include the above-described semiconductor devices 100, 200, 300, 300A, 300B, 300C, 400, 500, and 600 according to an embodiment.

In some embodiments, the processing circuitry 910 may be configured to control a function for driving the neuromorphic apparatus 900. For example, the processing circuitry 910 may be configured to control the neuromorphic apparatus 900 by executing a program stored in the on-chip memory 920. In some embodiments, the processing circuitry 910 may include hardware including a logic circuit, a combination of hardware and software, such as a processor for executing software, or a combination thereof. For example, the processor may include a CPU, a Graphics Processing Unit (GPU), an application processor (AP) included in the neuromorphic apparatus 900, an ALU, a digital signal processor, a microcomputer, a FPGA, an SoC, a programmable logic unit, a microprocessor, or an ASIC, but is not limited thereto. In some embodiments, the processing circuitry 910 may be configured to read/record various types of data from the external device 930 and/or to operate the neuromorphic apparatus 900 by using the read/recorded data. In some embodiments, the external device 930 may include an external memory and/or a sensor array including an image sensor (e.g., a CMOS image sensor circuit).

In some embodiments, the neuromorphic apparatus 900 may be applied to a machine learning system. The machine learning system may use various artificial neural network architectures, such as a Convolutional Neural Network (CNN), a deconvolution neural network, a Recurrent Neural Network (RNN) selectively including a Long Short-Term Memory (LSTM) unit and/or a Gated Recurrent Unit (GRU), a Stacked Neural Network (SNN), a State-space Dynamic Neural Network (SSDNN), a Deep Belief Network (DBN), a Generative Adversarial Network (GAN), and/or a Restricted Boltzmann Machine (RBM), and processing models.

Alternatively or additionally, the machine learning system may include other types of machine learning models, such as linear and/or logistic regression, statistical clustering, Bayesian classification, decision trees, dimensionality reduction like principle component analysis, expert systems, and/or combinations thereof that include ensembles, such as random forests. Such machine learning models may be used to provide various services and/or applications; for example, an image classification service, a user authentication service based on biometric information or biometric data, an Advanced Driver Assistance System (ADAS) service, a voice assistant service, an Automatic Speech Recognition (ASR) service, or the like may be executed by electronic apparatuses.

A semiconductor device according to an embodiment may be used for a transistor, a photoelectric cell, a thermoelectric element, a light-emitting diode, a display, or the like, as well as for DRAM, flash memory, a CMOS image sensor, or the like.

A semiconductor device according to an embodiment may include a p-type channel including In, Te, and O. A semiconductor device according to an embodiment may exhibit p-type channel characteristics by adjusting the composition of In, Te, and O.

One or more of the elements disclosed above may include or be implemented in processing circuitry such as hardware including logic circuits; a hardware/software combination such as a processor executing software; or a combination thereof. For example, the processing circuitry more specifically may include, but is not limited to, a central processing unit (CPU), an arithmetic logic unit (ALU), a digital signal processor, a microcomputer, a field programmable gate array (FPGA), a System-on-Chip (SoC), a programmable logic unit, a microprocessor, application-specific integrated circuit (ASIC), etc.

It should be understood that embodiments described herein should be considered in a descriptive sense only and not for purposes of limitation. Descriptions of features or aspects within each embodiment should typically be considered as available for other similar features or aspects in other embodiments. While one or more embodiments have been described with reference to the figures, it will be understood by those of ordinary skill in the art that various changes in form and details may be made therein without departing from the spirit and scope as defined by the following claims.

What is claimed is:

1. A semiconductor device comprising:
a channel;
a source electrode electrically connected to the channel;
a drain electrode electrically connected to the channel and spaced apart from the source electrode;
a gate insulating layer on the channel; and
a gate electrode on the gate insulating layer, wherein
the channel comprises InₐTe_{b}O_{c}, and
in InₐTe_{b}O_{c}, a+b=100, a<50, b>50, and c is less than a chemical stoichiometric value.

2. The semiconductor device of claim 1, wherein, in InₐTe_{b}O_{c},
a is in a range of 12 to 40, and
b is in a range of 60 to 88.

3. The semiconductor device of claim 1, wherein, in InₐTe_{b}O_{c}, a ratio of b/a is greater than 1 and less than or equal to 7.

4. The semiconductor device of claim 1, wherein an oxygen vacancy concentration in the channel is in a range of 5% to 80%.

5. The semiconductor device of claim 1, wherein
the source electrode is spaced apart from the drain electrode in a first direction,
the first direction is a same direction as a vertical direction of the semiconductor device, and
a longitudinal direction of each of the channel, the gate insulating layer, and the gate electrode is in the first direction.

6. The semiconductor device of claim 1, wherein
the channel comprises a bottom portion contacting the source electrode, a first vertical extension extending from one end of the bottom portion in a direction perpendicular to the source electrode, and a second vertical extension extending from an other end of the bottom portion in the direction perpendicular to the source electrode.

7. The semiconductor device of claim 1, wherein the gate insulating layer comprises a ferroelectric substance.

8. The semiconductor device of claim 7, wherein
the channel, the gate insulating layer, and the gate electrode are arranged concentrically,
the gate electrode comprises a first gate electrode and a second gate electrode that are spaced apart from each other, and
a spacer is between the first gate electrode and the second gate electrode.

9. A semiconductor device comprising:
a channel including an n-type first channel and a p-type second channel on the n-type first channel;
a source electrode and a drain electrode electrically connected to the channel;
a gate electrode spaced apart from the channel; and
a gate insulating layer between the channel and the gate electrode, wherein
the p-type second channel comprises InₐTe_{b}O_{c}, and
in InₐTe_{b}O_{c}, a+b=100, a<50, b>50, and c is less than a chemical stoichiometric value.

10. The semiconductor device of claim 9, wherein
a is in a range of 12 to 40, and
b is in a range of 60 to 88.

11. The semiconductor device of claim 9, wherein an oxygen vacancy concentration in the p-type second channel is in a range of 5% to 80%.

12. The semiconductor device of claim 9, wherein
the n-type first channel comprises an oxide comprising at least one of indium (In), zinc (Zn), tin (Sn), gallium (Ga), and hafnium (Hf).

13. An electronic apparatus comprising:
a host;
a memory apparatus comprising at least one semiconductor device; and
a memory controller configured to control, in response to a request from the host, the memory apparatus for at least one of a reading operation of data from the memory apparatus and a writing operation of data to the memory apparatus, wherein
each semiconductor device among the at least one semiconductor device includes the semiconductor device of claim 1.

14. The electronic apparatus of claim 13, wherein
a is in a range of 12 to 40, and
b is in a range of 60 to 88.

15. The electronic apparatus of claim 13, wherein
in InₐTe_{b}O_{c}, a ratio of b/a is greater than 1 and less than or equal to 7.

16. The electronic apparatus of claim 13, wherein an oxygen vacancy concentration in the channel is in a range of 5% to 80%.

17. The electronic apparatus of claim 13, further comprising:
an n-type channel between the source electrode and the channel,
wherein the n-type channel comprises an oxide including at least one of indium (In), zinc (Zn), tin (Sn), gallium (Ga), and hafnium (Hf).

18. A method of manufacturing a semiconductor device, the method comprising:
forming a channel on a substrate, the channel comprising indium (In), tellurium (Te), and oxygen (O);
adjusting a composition of the channel to form InₐTe_{b}O_{c}, wherein a<50, b>50, and c is less than a chemical stoichiometric value;
forming a source electrode on one surface of the channel and forming a drain electrode on an opposite surface of the channel;
forming a gate insulating layer on the channel; and
forming a gate electrode on the gate insulating layer.

19. The method of claim 18, wherein a is in a range of 12 to 40, and b is in a range of 60 to 88.

20. The method of claim 18, further comprising:
forming a p-type channel between the source electrode and the channel,
wherein the p-type channel comprises an oxide comprising at least one of indium (In), zinc (Zn), tin (Sn), gallium (Ga), and hafnium (Hf).
